(19) United States
(12) Patent Application Publication
(10) Pub. No.: US 2024/0407218 A1
(43) Pub. Date: Dec. 5, 2024

(54) DISPLAY SUBSTRATE AND DISPLAY DEVICE

(71) Applicant: BOE TECHNOLOGY GROUP CO., LTD., Beijing (CN)

(72) Inventors: Wenxiu ZHU, Beijing (CN); Hongli WANG, Beijing (CN)

(73) Assignee: BOE TECHNOLOGY GROUP CO., LTD., Beijing (CN)

(21) Appl. No.: 18/697,127

(22) PCT Filed: Aug. 25, 2023
(86) PCT No.: PCT/CN2023/114894

§ 371 Date: Mar. 29, 2024

(30) Foreign Application Priority Data
Aug. 26, 2022 (CN) 202211030963.7

(51) Int. Cl. H10K 59/35; H10K 59/80

(52) U.S. Cl. CPC H10K 59/353; H10K 59/352; H10K 59/8791

(57) ABSTRACT

A display substrate and a display device are provided. In the display substrate, a first pixel group includes a first sub-pixel, a second sub-pixel, and a third sub-pixel, arranged in sequence in a first direction; a power line extends in a second direction, and a value of an angle between the first direction and the second direction ranges from 30 to 60 degrees; the first sub-pixel includes a first edge and a second edge, and the third sub-pixel includes a third edge and a fourth edge, the first edge is disposed on a side of the second edge away from the second sub-pixel, the fourth edge is disposed on a side of the third edge away from the second sub-pixel, at least a part of the first edge is curved, and at least a part of the fourth edge is curved.

The present application claims priority of Chinese Patent Application No. 202211030963.7, filed on Aug. 26, 2022, the disclosure of which is incorporated herein by reference in its entirety as part of the present application.

### TECHNICAL FIELD

The present disclosure relates to a display substrate and a display device.

### BACKGROUND

With the continuous development of display technology, people have higher and higher requirements for the display quality of display devices. Due to the advantages of wide color gamut, fast response speed, flexible display, bendability, and high contrast ratio, organic light emitting diode (OLED) display devices are being applied more and more widely.

On the other hand, people have higher and higher requirements for the screen ratio of display devices such as smart phones and tablet computers. The design of setting some functional components of these display devices under the screen has become a new research hotspot. For example, the under-screen camera design achieves an ultra-high screen ratio by setting the camera of the display device under the screen. In the display device designed with under-screen camera, because the camera needs light to pass through the screen, the screen needs to be provided with a first display area that can not only display, but also allow light to pass through.

### SUMMARY

Embodiments of the present disclosure provide a display substrate and a display device. The display substrate sets the angle between the arrangement direction of the first sub-pixel, the second sub-pixel and the third sub-pixel and the extending direction of the power line to 30-60 degrees, thereby improving the display quality; on the other hand, the display substrate sets the first edge and the fourth edge as curved edges, which can make the outer edges of the first sub-pixel and the third sub-pixel have no angles and be smoother to avoid the diffraction phenomenon of external light on the outer edges of the first sub-pixel and the third sub-pixel, thereby improving the photosensitive quality of the photosensitive device arranged in the first display area. As a result, the display substrate can simultaneously have higher photosensitive quality and display quality.

At least one embodiment of the present disclosure provides a display substrate, which includes: a base substrate, comprising a first display area and a second display area; a first pixel group, located in the first display area and comprising a first sub-pixel, a second sub-pixel, and a third sub-pixel; and a power line, located in the second display area, in the first pixel group, the first sub-pixel, the second sub-pixel, and the third sub-pixel are arranged in sequence in a first direction; the power line extends in a second direction, and a value of an angle between the first direction and the second direction ranges from 30 to 60 degrees; the first sub-pixel includes a first edge and a second edge disposed opposite each other in the first direction, and the third sub-pixel includes a third edge and a fourth edge disposed opposite each other in the first direction, the first edge is disposed on a side of the second edge away from the second sub-pixel, the fourth edge is disposed on a side of the third edge away from the second sub-pixel, at least a part of the first edge is curved, and at least a part of the fourth edge is curved.

For example, in the display substrate provided by an embodiment of the present disclosure, the first edge is a first curved edge and the fourth edge is a second curved edge.

For example, in the display substrate provided by an embodiment of the present disclosure, a pixel density of the first display area is less than a pixel density of the second display area, and an included angle between the first direction and the second direction ranges from 40 to 50 degrees.

For example, the display substrate provided by an embodiment of the present disclosure further includes: a second pixel group, located in the second display area and includes a fourth sub-pixel, a fifth sub-pixel, and a sixth sub-pixel; in the second pixel group, the fourth sub-pixel, the fifth sub-pixel, and the sixth sub-pixel are arranged in sequence along a third direction; the first sub-pixel and the fourth sub-pixel are configured to emit light of a first color, the second sub-pixel and the fifth sub-pixel are configured to emit light of a second color, and the third sub-pixel and the sixth sub-pixel are configured to emit light of a third color; an area of the first sub-pixel is larger than an area of the fourth sub-pixel, and/or, an area of the second sub-pixel is larger than an area of the fifth sub-pixel, and/or, an area of the third sub-pixel is larger than an area of the sixth sub-pixel.

For example, in the display substrate provided by an embodiment of the present disclosure, an extending direction of the first sub-pixel and an extending direction of the fourth sub-pixel are the same or parallel.

For example, in the display substrate provided by an embodiment of the present disclosure, a symmetry axis of at least one first sub-pixel and a symmetry axis of one fourth sub-pixel are located on the same straight line.

For example, in the display substrate provided by an embodiment of the present disclosure, an angle between the first direction and the third direction is in a range of 0-10 degrees.

For example, in the display substrate provided by an embodiment of the present disclosure, the first direction and the third direction are parallel to each other.

For example, the display substrate provided by an embodiment of the present disclosure further includes: a light-shielding structure, located in the first display area; an orthographic projection of the first edge of the first sub-pixel on the base substrate is overlapped with an orthographic projection of the light-shielding structure on the base substrate; an orthographic projection of the fourth edge of the third sub-pixel on the base substrate is overlapped with the orthographic projection of the light-shielding structure on the base substrate, an outline of the light-shielding structure is a shape surrounded by arcs; alternatively, an outline of the light-shielding structure is a shape surrounded by arcs and a straight line segment, and both ends of the straight line segments are connected to the arcs.

For example, in the display substrate provided by an embodiment of the present disclosure, a shape of the orthographic projection of the light-shielding structure on the base substrate does not include an angle, the angle being formed by an intersection of two straight line segments.

For example, in the display substrate provided by an embodiment of the present disclosure, at least a part of the outline of the light-shielding structure is overlapped with a part of an edge of at least one sub-pixel of the first sub-pixel, the second sub-pixel, and the third sub-pixel.

For example, in the display substrate provided by an embodiment of the present disclosure, at least a part of the outline of the light-shielding structure has intersections with an edge of the first sub-pixel, an edge of the second sub-pixel, and an edge of the third sub-pixel.

For example, in the display substrate provided by an embodiment of the present disclosure, orthographic projections of the first sub-pixel, the second sub-pixel, and the third sub-pixel of the first pixel group on the base substrate are located within the orthographic projection of the light-shielding structure on the base substrate.

For example, in the display substrate provided by an embodiment of the present disclosure, a shape of an orthographic projection of the light-shielding structure on the base substrate comprises at least one of a circle, an ellipse and a rounded rectangle.

For example, in the display substrate provided by an embodiment of the present disclosure, at least a part of at least one of the first edge and the fourth edge is overlapped with an edge of the orthographic projection of the light-shielding structure on the base substrate.

For example, in the display substrate provided by an embodiment of the present disclosure, the first edge and the fourth edge both have at least a part overlapping with an edge of an orthographic projection of the light-shielding structure on the base substrate.

For example, in the display substrate provided by an embodiment of the present disclosure, the second edge is a third curved edge and the third edge is a fourth curved edge.

For example, in the display substrate provided by an embodiment of the present disclosure, the second sub-pixel further comprises a fifth curved edge and a sixth curved edge disposed opposite to each other in the first direction, the fifth curved edge is disposed opposite to and spaced apart from the third curved edge, and the sixth curved edge is disposed opposite to and spaced apart from the fourth curved edge, points on the fifth curved edge have substantially equal shortest distances from the third curved edge, and points on the sixth curved edge have substantially equal shortest distances from the fourth curved edge.

For example, in the display substrate provided by an embodiment of the present disclosure, a shortest distance between points on the fifth curved edge and the third curved edge is a first distance, and a shortest distance between points on the sixth curved edge and the fourth curved edge is a second distance, the first distance and the second distance are equal.

For example, in the display substrate provided by an embodiment of the present disclosure, the second sub-pixel further comprises a seventh curved edge and an eighth curved edge disposed opposite each other in a fourth direction that is perpendicular to the first direction, at least one of the seventh curved edge and the eighth curved edge is overlapped with an edge of an orthographic projection of the light-shielding structure on the base substrate.

For example, in the display substrate provided by an embodiment of the present disclosure, the second edge of the first sub-pixel is a first straight edge, and the third edge of the third sub-pixel is a second straight edge, the second sub-pixel comprises a third straight edge and a fourth straight edge disposed opposite each other in the first direction, the third straight edge is disposed on a side of the fourth straight edge away from the third sub-pixel.

For example, in the display substrate provided by an embodiment of the present disclosure, the first straight edge and the third straight edge are parallel to each other and have a third distance, the second straight edge and the fourth straight edge are parallel to each other and have a fourth distance.

For example, in the display substrate provided by an embodiment of the present disclosure, the third distance and the fourth distance are equal.

For example, in the display substrate provided by an embodiment of the present disclosure, a geometric center of an orthographic projection of the light-shielding structure on the base substrate is located between the first sub-pixel and the third sub-pixel.

For example, in the display substrate provided by an embodiment of the present disclosure, a maximum distance between the first edge and the second edge is smaller than a maximum distance between the third edge and the fourth edge.

For example, in the display substrate provided by an embodiment of the present disclosure, a shape of the first sub-pixel comprises a first ellipse, two intersections of the first edge and the second edge are located on a long axis of the first ellipse.

For example, in the display substrate provided by an embodiment of the present disclosure, a shape of the third sub-pixel comprises a second ellipse, two intersections of the third edge and the fourth edge are located on a long axis of the second ellipse.

For example, in the display substrate provided by an embodiment of the present disclosure, a shape of the second sub-pixel comprises a third ellipse, the second sub-pixel further includes a fifth edge and a sixth edge disposed opposite each other in the first direction, two intersections of the fifth edge and the sixth edge are located on a long axis of the third ellipse.

For example, in the display substrate provided by an embodiment of the present disclosure, a shape of the first sub-pixel comprises a first circle, two intersections of the first edge and the second edge are located on a virtual straight line perpendicular to the first direction and through a center of the first circle.

For example, in the display substrate provided by an embodiment of the present disclosure, a shape of the third sub-pixel comprises a second circle, two intersections of the third edge and the fourth edge are located on a virtual straight line perpendicular to the first direction and through a center of the second circle.

For example, in the display substrate provided by an embodiment of the present disclosure, a shape of the second sub-pixel comprises a third circle, the second sub-pixel further comprises a fifth edge and a sixth edge disposed opposite each other in the first direction, two intersections of the fifth edge and the sixth edge are located on a virtual straight line perpendicular to the first direction and through a center of the third circle.

For example, in the display substrate provided by an embodiment of the present disclosure, the second edge is a first straight edge, and the third edge is a second straight edge, the second sub-pixel comprises a third straight edge and a fourth straight edge disposed opposite each other in the first direction, the third straight edge is disposed on a side of the fourth straight edge away from the third sub-pixel.

For example, in the display substrate provided by an embodiment of the present disclosure, the first display area comprises a plurality of cell areas that are closely disposed, one cell area in every N cell areas in the plurality of cell areas is overlapped with an orthographic projection of the first pixel group on the base substrate, wherein a value of N is in a range of 3-8.

For example, in the display substrate provided by an embodiment of the present disclosure, shapes of the fourth sub-pixel, the fifth sub-pixel, and the sixth sub-pixel are all rectangles or rounded rectangles.

At least one embodiment of the present disclosure further provides a display device, which includes any one of the abovementioned display substrates.

For example, the display device provided by an embodiment of the present disclosure, further includes: a light-sensitive device, an orthographic projection of the light-sensitive device on the base substrate is located in the first display area.

### BRIEF DESCRIPTION OF DRAWINGS

In order to more clearly explain the technical solution of the embodiments of the present disclosure, the accompanying drawings of the embodiments will be briefly introduced below. Obviously, the accompanying drawings in the following description only relate to some embodiments of the present disclosure, and are not limited to the present disclosure.

FIG. 1 is a schematic planar diagram of a display substrate provided by an embodiment of the present disclosure.

FIG. 2 is a local schematic planar diagram of a display substrate provided by an embodiment of the present disclosure.

FIG. 3 is a local schematic planar diagram of another display substrate provided by an embodiment of the present disclosure.

FIG. 4 is a local schematic planar diagram of another display substrate provided by an embodiment of the present disclosure.

FIG. 5 is a local schematic planar diagram of another display substrate provided by an embodiment of the present disclosure.

FIG. 6 is a local schematic planar diagram of another display substrate provided by an embodiment of the present disclosure.

FIG. 7 is a local schematic planar diagram of another display substrate provided by an embodiment of the present disclosure.

FIG. 8 is a local schematic planar diagram of another display substrate provided by an embodiment of the present disclosure.

FIG. 9 is a connection diagram of a pixel driving circuit of a display substrate provided by an embodiment of the present disclosure.

FIG. 10 is a connection diagram of a pixel driving circuit of another display substrate provided by an embodiment of the present disclosure.

FIGS. 11A-11D are schematic planar diagrams of a first pixel group of a display substrate provided by an embodiment of the present disclosure.

FIG. 12 is a diagram of a display device provided by an embodiment of the present disclosure.

### DETAILED DESCRIPTION

In order to make the purpose, technical scheme and advantages of the embodiment of the disclosure more clear, the technical scheme of the embodiment of the disclosure will be described clearly and completely with the accompanying drawings. Obviously, the described embodiment is a part of the embodiment of the present disclosure, not the whole embodiment. Based on the described embodiments of the present disclosure, all other embodiments obtained by ordinary people in the field without creative labor belong to the scope of protection of the present disclosure.

Unless otherwise defined, technical terms or scientific terms used in the present disclosure shall have their ordinary meanings as understood by people with ordinary skills in the field to which the present disclosure belongs. The terms “first”, “second” and the like used in the present disclosure do not indicate any order, quantity or importance, but are only used to distinguish different components. Similar words such as “including” or “comprising” refer to that the elements or objects appearing before the word cover the elements or objects listed after the word and their equivalents, without excluding other elements or objects. Similar words such as “connected” or “connected” are not limited to physical or mechanical connection, but may include electrical connection, whether direct or indirect.

Organic light emitting diode (OLED) display devices employ a variety of pixel arrangements to achieve high pixel aperture ratio and high resolution. However, these pixel arrangement methods can introduce some display defects to varying degrees.

On the other hand, a display device employing under-screen camera technology typically includes a transparent display area that enables both light-emitting display and allows light to pass through, and the transparent display area can correspond to the installation of a light-sensitive device such as a camera, thereby realizing an under-screen camera design. However, the inventor(s) of the present application has found in their research that external light diffracts on the edges of pixels used for the light-emitting display in the transparent display area, thereby affecting the imaging quality of the camera. As a result, how to design a reasonable pixel arrangement in the transparent display area to improve the imaging quality of the camera and give consideration to the display quality is an urgent technical problem to be solved.

In this regard, an embodiment of the present disclosure provides a display substrate and a display device. The display substrate includes a base substrate, a first pixel group, and a power line; the base substrate includes a first display area and a second display area; the first pixel group is located in the first display area and includes a first sub-pixel, a second sub-pixel, and a third sub-pixel; the power line is located in the second display area; the first sub-pixel, the second sub-pixel, and the third sub-pixel are arranged in sequence in a first direction in the first pixel group; the power line extends in a second direction, and the value of an angle between the first direction and the second direction ranges from 30 to 60 degrees; the first sub-pixel includes a first edge and a second edge disposed opposite each other in the first direction, and the third sub-pixel includes a third edge and a fourth edge disposed opposite each other in the first direction, the first edge is disposed on a side of the second edge away from the second sub-pixel, the fourth edge is disposed on a side of the third edge away from the second sub-pixel, at least a part of the first edge is curved, and at least a part of the fourth edge is curved. As a result, the display substrate sets the angle between the arrangement direction of the first sub-pixel, the second sub-pixel and the third sub-pixel and the extending direction of the power line to 30-60 degrees, thereby improving the display quality; on the other hand, the display substrate sets at least a part of the first edge and at least a part of the fourth edge to be curved, which can make the outer edges of the first sub-pixel and the third sub-pixel have no angles and be smoother to avoid the diffraction phenomenon of external light on the outer edges of the first sub-pixel and the third sub-pixel, thereby improving the photosensitive quality of the photosensitive device arranged in the first display area. As a result, the display substrate can simultaneously have higher photosensitive quality and display quality.

Hereinafter, the display substrate and the display device provided by embodiments of the present disclosure are described in detail with reference to the diagrams.

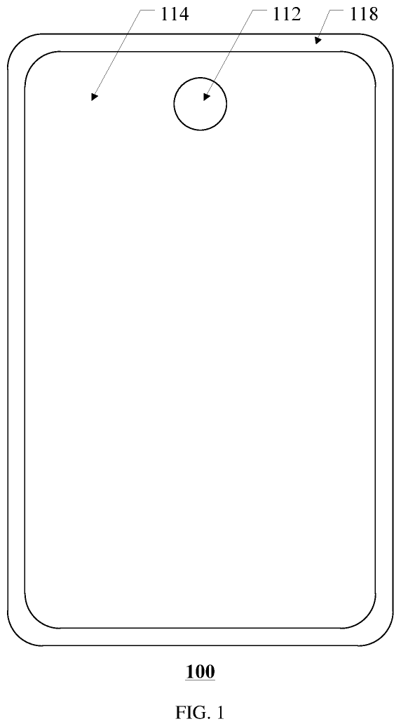

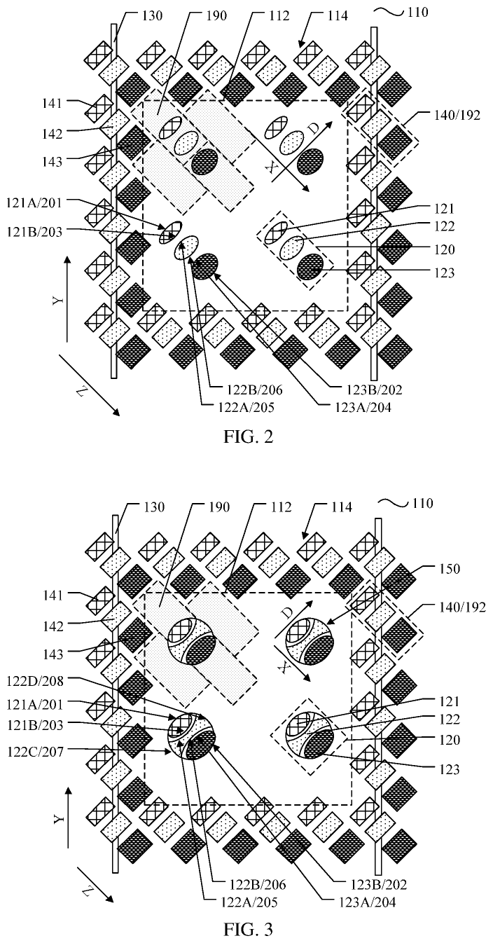

An embodiment of the present disclosure provides a display substrate. FIG. 1 is a schematic planar diagram of a display substrate provided by an embodiment of the present disclosure. FIG. 2 is a local schematic planar diagram of a display substrate provided by an embodiment of the present disclosure.

As illustrated by FIGS. 1 and 2, the display substrate 100 includes a base substrate 110, a first pixel group 120, and a power line 130. The base substrate 110 includes a display area and a peripheral area 118 surrounding the display area, the display area including a first display area 112 and a second display area 114; all of the display area of the display substrate are capable of light-emitting display, i.e., both the first display area 112 and the second display area 114 are capable of light-emitting display. The first pixel group 120 is located in the first display area 112 and includes a first sub-pixel 121, a second sub-pixel 122, and a third sub-pixel 123; the power line 130 is located in the second display area 114.

As illustrated by FIG. 2, in the first pixel group 120, the first sub-pixel 121, the second sub-pixel 122, and the third sub-pixel 123 are sequentially arranged along a first direction X; the power line 130 extends along a second direction Y, and an angle between the first direction X and the second direction Y ranges from 30 to 60 degrees. The first sub-pixel 121 includes a first edge 121A and a second edge 121B disposed opposite each other in the first direction X, the third sub-pixel 123 includes a third edge 123A and a fourth edge 123B disposed opposite each other in the first direction X, the first edge 121A is disposed on the side of the second edge 121B away from the second sub-pixel 122, the fourth edge 123B is disposed on the side of the third edge 123A away from the second sub-pixel 122, at least a part of the first edge 121A is curved, and at least a part of the fourth edge 123B is curved. It is noted that the shape and range of each of the above-described sub-pixels (e.g., the first sub-pixel, the second sub-pixel, and the third sub-pixel) can be determined by the shape and range of the effective light-emitting area of each of the sub-pixels, and accordingly the edges of each of the sub-pixels (e.g., the first edge, the second edge, the third edge, and the fourth edge) can be the edges of the effective light-emitting area of each of the sub-pixels. Of course, embodiments of the present disclosure include, but are not limited thereto, that the above-described shape and range of each sub-pixel can also be determined by the shape and range of the pixel opening defined by the pixel-defining layer of each sub-pixel, and so the edge of each sub-pixel can also be an edge of the pixel opening of each sub-pixel.

In the display substrate provided by embodiments of the present disclosure, the angle between the arrangement direction of the first sub-pixel, the second sub-pixel, and the third sub-pixel and the extending direction of the power line is set to 30-60 degrees. As a result, the display substrate is not prone to cause a color deviation phenomenon of lines or image edges when displaying lines and image edges extending in different directions. Moreover, when displaying oblique lines, display defects such as a “step” feeling or a “jagged” feeling of the oblique lines can be significantly reduced, thereby improving the display quality of the display substrate; on the other hand, the display substrate sets at least a part of the first edge of the first sub-pixel and at least a part of the fourth edge of the third sub-pixel to be curved, which can make the outer edges of the first sub-pixel and the third sub-pixel have no angles and be smoother to avoid the diffraction phenomenon of external light on the outer edges of the first sub-pixel and the third sub-pixel, thereby improving the photosensitive quality of the photosensitive device arranged in the first display area. For example, in the case where the light-sensitive device is a camera, the above-described light-sensitive quality is the imaging quality. As a result, the display substrate can simultaneously have higher photosensitive quality and display quality.

For example, the first edge 121A is a first curved edge 201 and the fourth edge 123B is a second curved edge 202.

In some embodiments, the above-described first direction can be an extending direction of a line connecting the centers of the first sub-pixel, the second sub-pixel, and the third sub-pixel; alternatively, a straight line extending along the first direction can divide the first sub-pixel, the second sub-pixel, and the third sub-pixel into two parts, respectively, with a ratio of the areas of the two parts ranging from 0.5-2.

In some embodiments, the first edge and the second edge can be two continuous edges separated by a straight line perpendicular to the first direction. Of course, embodiments of the present disclosure include, but are not limited thereto, the above-described first edge and second edge can also be two edges that are not connected. In some embodiments, as illustrated by FIG. 2, the second display area 114 surrounds the first display area 112. Of course, embodiments of the present disclosure include, but are not limited thereto, that the second display area can also be located on at least one side of the first display area.

In some embodiments, as illustrated by FIG. 2, the pixel density (PPI, Pixels Per Inch) of the first display area 112 is less than the pixel density of the second display area 114. As a result, the first display area also includes an area that allows light to pass through, so that both a display function can be realized and light can be allowed to pass through to arrange the light-sensitive device.

In some embodiments, as illustrated by FIG. 2, the value of an angle between the first direction X and the second direction Y is in the range of 40-50 degrees. For example, the angle between the first direction X and the second direction Y is 45 degrees; for another example, the angle between the first direction X and the second direction Y is 43 degrees; for another example, the angle between the first direction X and the second direction Y is 44 degrees; for another example, the angle between the first direction X and the second direction Y is 46 degrees; for another example, the angle between the first direction X and the second direction Y is 47 degrees; for another example, the angle between the first angle between the first direction X and the second direction Y is 48 degrees. In some embodiments, as illustrated by FIG. 2, the display substrate 100 further includes a second pixel group 140; the second pixel group 140 is located in the second display area 114 and includes a fourth sub-pixel 141, a fifth sub-pixel 142, and a sixth sub-pixel 143; in the second pixel group 140, the fourth sub-pixel 141, the fifth sub-pixel 142, and the sixth sub-pixel 143 are arranged in sequence along a third direction Z. As a result, in the second display area, the display substrate is not prone to cause a color deviation phenomenon of lines or image edges when displaying lines and image edges extending in different directions. Moreover, when displaying oblique lines, display defects such as a “step” feeling or a “jagged” feeling of the oblique lines can be significantly reduced, thereby improving the display quality of the display substrate.

In some embodiments, the angle between the first direction X and the third direction Z is in the range of 0-10 degrees. For example, as illustrated by FIG. 2, the first direction X and the third direction Z are parallel to each other.

In some embodiments, as illustrated by FIG. 2, the first sub-pixel 121 and the fourth sub-pixel 141 are configured to emit light of a first color, the second sub-pixel 122 and the fifth sub-pixel 142 are configured to emit light of a second color, and the third sub-pixel 123 and the sixth sub-pixel 143 are configured to emit light of a third color. The area of the first sub-pixel 121 is larger than the area of the fourth sub-pixel 141, and/or, the area of the second sub-pixel 122 is larger than the area of the fifth sub-pixel 142, and/or, the area of the third sub-pixel 123 is larger than the area of the sixth sub-pixel 143; that is to say, the area of at least one of the first sub-pixel, the second sub-pixel, and the third sub-pixel in the first display area can be larger than the area of the sub-pixel emitting light of a corresponding color in the second display area. Because the brightness of the first pixel group in the first display area is greater than the brightness of the second pixel group in the second display area, the display substrate can increase service life by increasing the area of at least one of the first sub-pixel, the second sub-pixel, and the third sub-pixel.

In some embodiments, as illustrated by FIG. 2, the extending direction of the first sub-pixel 121 and the extending direction of the fourth sub-pixel 141 are the same or parallel.

In some embodiments, as illustrated by FIG. 2, a symmetry axis of at least one of the first sub-pixels 121 and a symmetry axis of one of the fourth sub-pixels 141 are located on the same straight line.

For example, the first color is red, the second color is green, and the third color is blue. Of course, embodiments of the present disclosure include, but are not limited thereto.

In some embodiments, as illustrated by FIG. 2, the first display area 112 includes a plurality of cell areas 190 that are closely disposed, every N cell area 190 are provided with one first pixel group 120; an orthographic projection of the first pixel group 120 on the base substrate is overlapped with at least one of the cell areas 190, and the value of N is in the range of 3-8. That is, every N cell areas are provided with one first pixel group, and the areas of the N cell areas in which the first pixel group is not arranged can allow light to pass through. As a result, the first display area can realize light-emitting display and allow light to pass through. Moreover, in the case where the value of N is in the range of 3-8, the display quality and the light transmission rate of the first display area are at a good level at the same time. It should be noted that in order to ensure the display quality of the first display area, the brightness of the individual first pixel group is larger than the brightness of the second pixel group.

In some embodiments, as illustrated by FIG. 2, the second display area 114 can also include a plurality of second cell areas 192 that are closely disposed, one second cell area 192 is provided with one second pixel group 140, and the fourth sub-pixel 141, the fifth sub-pixel 142, and the sixth sub-pixel 143 in the second pixel group 140 are all disposed within the corresponding second cell area 192. The first cell area 190 has the same area as the second cell area 192.

In some embodiments, as illustrated by FIG. 2, every four cell areas 190 are provided with one first pixel group 120. At this time, the display substrate has a better display quality and a better light transmission rate.

In some embodiments, as illustrated by FIG. 2, the fourth sub-pixel 141, the fifth sub-pixel 142, and the sixth sub-pixel 143 are all shaped as rectangles or rounded rectangles. Of course, embodiments of the present disclosure include, but are not limited thereto, the shapes of the fourth sub-pixel, the fifth sub-pixel, and the sixth sub-pixel can also include shapes such as a circle, hexagon, octagon, rhombus, trapezoid, and the like.

In some embodiments, as illustrated by FIG. 2, the maximum distance between the first edge 121A and the second edge 121B is less than the maximum distance between the third edge 123A and the fourth edge 123B. As a result, the area of the first sub-pixel is smaller than the area of the third sub-pixel, thereby ensuring that the first sub-pixel and the third sub-pixel have a consistent service life.

In some embodiments, as illustrated by FIG. 2, the first edge 121A is a first curved edge 201 and the fourth edge 123B is a second curved edge 202; in this case, the radius of curvature of the first curved edge 201 is larger than the radius of curvature of the second curved edge 202.

In some embodiments, as illustrated by FIG. 2, the shape of the first sub-pixel 121 includes a first ellipse, and two intersections of the first edge 121A and the second edge 121B are located on the long axis of the first ellipse. As a result, the display substrate, by setting the shape of the first sub-pixel as an ellipse, can make both the first edge and the second edge to be curved edges, so that the diffraction phenomenon of light rays on the edges of the first sub-pixel can be better avoided.

For example, as illustrated by FIG. 2, the long axis of the first ellipse is perpendicular to the first direction X, thereby allowing the first sub-pixel to occupy less space in the first direction X and improving the pixel resolution.

In some embodiments, as illustrated by FIG. 2, a shape of the third sub-pixel 123 includes a second ellipse, two intersections of the third edge 123A and the fourth edge 123B are located on the long axis of the second ellipse. As a result, by setting the shape of the third sub-pixel as an ellipse, the display substrate can make both the third edge and the fourth edge to be curved edges, so that the diffraction phenomenon of light rays on the edges of the third sub-pixel can be better avoided.

For example, as illustrated by FIG. 2, the long axis of the second ellipse is perpendicular to the first direction X, thereby allowing the third sub-pixel to occupy less space in the first direction X and improving the pixel resolution.

In some embodiments, as illustrated by FIG. 2, a shape of the second sub-pixel 122 includes a third ellipse, and the second sub-pixel 122 further includes a fifth edge 122A and a sixth edge 122B disposed opposite each other in the first direction X, two intersections of the fifth edge 122A and the sixth edge 122B are located on the long axis of the third ellipse. As a result, by setting the shape of the second sub-pixel as an ellipse, the display substrate can make both the fifth edge and the sixth edge to be curved edges, so that the diffraction phenomenon of light rays on the edges of the second sub-pixel can be better avoided.

For example, as illustrated by FIG. 2, the long axis of the third ellipse is perpendicular to the first direction X, thereby allowing the second sub-pixel to occupy less space in the first direction X, increasing the pixel resolution.

In some embodiments, as illustrated by FIG. 2, an area of the first ellipse is smaller than an area of the second ellipse, and an area of the second ellipse is smaller than an area of the third ellipse, thereby balancing the service life of the first sub-pixel, second sub-pixel and third sub-pixel.

In some embodiments, as illustrated by FIG. 2, the length of the long axis of the first ellipse, the length of the long axis of the second ellipse, and the length of the long axis of the third ellipse are approximately equal. With this arrangement, the display substrate can cause the first sub-pixel, the second sub-pixel, and the third sub-pixel to have substantially equal dimensions in the fourth direction D, so that the display quality can be improved when displaying a beveled edge or a beveled line.

In some embodiments, as illustrated by FIG. 2, the ratio of the area of the first ellipse, the area of the second ellipse, and the area of the third ellipse is 1:1.3:1.7, thereby making the service life of the first sub-pixel, the second sub-pixel, and the third sub-pixel substantially equal.

It is worth noting that, although the first sub-pixel, the second sub-pixel, and the third sub-pixel shown in FIG. 2 are all elliptical, embodiments of the present disclosure include, but are not limited thereto, the shapes of the first sub-pixel, the second sub-pixel, and the third sub-pixel can include other shapes such as a circle, an arch, and other shapes that include curved edges.

FIG. 3 is a local schematic planar diagram of another display substrate provided by an embodiment of the present disclosure. FIG. 3 shows a partial plan view of another display substrate provided by an embodiment of the present disclosure. As illustrated by FIG. 3, the display substrate 100 includes a base substrate 110, a first pixel group 120, and a power line 130. the base substrate 110 includes a first display area 112 and a second display area 114; both the first display area 112 and the second display area 114 are capable of light-emitting display. The first pixel group 120 is located in the first display area 112 and includes a first sub-pixel 121, a second sub-pixel 122, and a third sub-pixel 123; the power line 130 is located in the second display area 114.

As illustrated by FIG. 3, in the first pixel group 120, the first sub-pixel 121, the second sub-pixel 122, and the third sub-pixel 123 are sequentially arranged along the first direction X; the power line 130 extends along the second direction Y, and the angle between the first direction X and the second direction Y is in the range of 30-60 degrees. The first sub-pixel 121 includes a first edge 121A and a second edge 121B disposed opposite each other in the first direction X, and the third sub-pixel 123 includes a third edge 123A and a fourth edge 123B disposed opposite each other in the first direction X, the first edge 121A is disposed on a side of the second edge 121B away from the second sub-pixel 122, and the fourth edge 123B is disposed on a side of the third edge 123A away from the second sub-pixel 122.

As illustrated by FIG. 3, the display substrate 100 further includes a light-shielding structure 150; the light-shielding structure 150 is located in the first display area 112; orthographic projections of the first sub-pixel 121, the second sub-pixel 122, and the third sub-pixel 123 in the first pixel group 120 on the base substrate 110 are all overlapped with the orthographic projection of the light-shielding structure 150 on the base substrate 110; an orthographic projection of the first curved edge 201 of the first sub-pixel 121 on the base substrate 110 is overlapped with the orthographic projection of the light-shielding structure 150 on the base substrate 110; an orthographic projection of the second curved edge 202 of the third sub-pixel 123 on the base substrate 110 is overlapped with the orthographic projection of the light-shielding structure 150 on the base substrate. The shape of the orthographic projection of the light-shielding structure 150 on the base substrate 110 does not include angles, the above-described angles are formed by the intersection of two straight line segments, and light rays tend to produce diffraction phenomenon at the angles.

In this display substrate, orthographic projections of the first sub-pixel, the second sub-pixel, and the third sub-pixel of the first pixel group on the base substrate are all overlapped with the orthographic projection of the light-shielding structure on the base substrate; the orthographic projection of the first curved edge of the first sub-pixel on the base substrate is overlapped with the orthographic projection of the light-shielding structure on the base substrate; the orthographic projection of the second curved edge of the third sub-pixel on the base substrate is overlapped with the orthographic projection of the light-shielding structure on the base substrate, and the light cannot pass through the light-shielding structure. As a result, it is no longer the edges of the sub-pixels but the edges of the light-shielding structure that have an effect on the light transmitted through the first display area, except for the first curved edge and the second curved edge. The display substrate, by setting the orthographic projection of the light-shielding structure on the base substrate to exclude an angle (e.g., a right angle, an obtuse angle, an acute angle, etc.), can avoid diffraction phenomenon of external light on the outer edges of the light-shielding structure, and thereby can enhance the light-sensitive quality of the light-sensitive device provided in the first display area. It is to be noted that the above-described light-shielding structure can be a light-shielding layer provided in a single layer, or can be a combination of light-shielding layers located in different layers.

In some embodiments, as illustrated by FIG. 3, the outline of the light-shielding structure 150 is a shape surrounded by arcs; alternatively, the outline of the light-shielding structure 150 is a shape surrounded by arcs and a straight line segment, and both ends of the straight line segment are connected to the arcs.

In some embodiments, the orthographic projections of the first sub-pixel 121, the second sub-pixel 122, and the third sub-pixel 123 of the first pixel group 120 on the base substrate 110 are located within the orthographic projection of the light-shielding structure 150 on the base substrate 110. As a result, it is no longer the edges of the sub-pixels, but the edges of the light-shielding structure, that have an effect on the light transmitted through the first display area. The display substrate, by setting the orthographic projection of the light-shielding structure on the base substrate to exclude an angle (e.g., a right angle, an obtuse angle, an acute angle, etc.), can avoid diffraction phenomenon of external light on the outer edges of the light-shielding structure, and thereby can enhance the light-sensitive quality of the light-sensitive device provided in the first display area.

In some embodiments, as illustrated by FIG. 3, the shape of an orthographic projection of the light-shielding structure 150 on the base substrate 110 includes a circle. In this case, the display substrate can better avoid diffraction phenomenon of external light on the outer edges of the light-shielding structure. Of course, embodiments of the present disclosure include, but are not limited thereto, the shape of the orthographic projection of the light-shielding structure on the base substrate can also be other shapes, such as ellipses and rounded rectangles.

In some embodiments, as illustrated by FIG. 3, at least a part of the outline of the light-shielding structure 150 is overlapped with a part of an edge of at least one sub-pixel of the first sub-pixel 121, the second sub-pixel 122, and the third sub-pixel 123. As a result, the display substrate can fully utilize the area covered by the light-shielding structure to arrange the above-described sub-pixels. It is worth noting that, the above-described edge can be an edge having a certain width, for example, an area extending 1 micrometer from the outline of each sub-pixel toward the center of the sub-pixel are all the edge of the sub-pixel.

In some embodiments, as illustrated by FIG. 3, at least a part of the outline of the light-shielding structure 150 has intersections with an edge of the first sub-pixel 121, an edge of the second sub-pixel 122, and an edge of the third sub-pixel 123. As a result, the display substrate can fully utilize the area covered by the light-shielding structure to arrange the above-described sub-pixels.

In some embodiments, as illustrated by FIG. 3, at least a part of at least one of the first curved edge 201 of the first sub-pixel 121 and the second curved edge 202 of the third sub-pixel 123 is overlapped with the edge of the orthographic projection of the light-shielding structure 150 on the base substrate 110. With this arrangement, in addition to avoiding diffraction phenomenon of external light on the outer edges of the light-shielding structure, the display substrate can also fully utilize the space covered by the light-shielding structure and increase the area of the first sub-pixel and the area of the third sub-pixel.

In some embodiments, as illustrated by FIG. 3, the first curved edge 201 of the first sub-pixel 121 and the second curved edge 202 of the third sub-pixel 123 both have at least a part overlapping with an orthographic projection of the light-shielding structure 150 on the base substrate 110. With this arrangement, in avoiding diffraction phenomenon of external light on the outer edges of the light-shielding structure, the display substrate can further utilize the space covered by the light-shielding structure to increase the area of the first sub-pixel and the third sub-pixel.

It is worth noting that, the above-described edges such as the first curved edge and the second curved edge can be an area formed by extending one micrometer from an outermost boundary of each sub-pixel toward a center of each sub-pixel.

In some embodiments, as illustrated by FIG. 3, the trend of the outline of the light-shielding structure 150 and the outline of the first sub-pixel 121 are at least partially the same or overlapped with each other; and the trend of the outline of the light-shielding structure 150 and the outline of the third sub-pixel 123 are at least partially the same or overlapped with each other.

In some embodiments, as illustrated by FIG. 3, a geometric center of an orthographic projection of the light-shielding structure 150 on the base substrate 110 is located between the first sub-pixel 121 and the third sub-pixel 123. As a result, the display substrate can keep the center of brightness of the first pixel group as a whole located at the geometric center of the orthographic projection of the light-shielding structure on the base substrate as much as possible, thereby improving the display quality.

In some embodiments, as illustrated by FIG. 3, the second edge 121B is a third curved edge 203 and the third edge 123A is a fourth curved edge 204.

In some examples, as illustrated by FIG. 3, the second sub-pixel 122 further includes a fifth curved edge 205 and a sixth curved edge 206 disposed opposite to each other in the first direction X, the fifth curved edge 205 is disposed opposite to and spaced apart from the third curved edge 203, and the sixth curved edge 206 is disposed opposite to and spaced apart from the fourth curved edge 204, the points on the fifth curved edge 205 have substantially equal shortest distances from the third curved edge 203, and the points on the sixth curved edge 206 have substantially equal shortest distances from the fourth curved edge 204. With this arrangement, the spacing between the fifth curved edge and the third curved edge can be the minimum spacing allowed by the process, and the spacing between the sixth curved edge and the fourth curved edge can also be the minimum spacing allowed by the process, thereby the display substrate can further increase the utilization rate of the space covered by the light-shielding structure, and increase the area of the first sub-pixel, the second sub-pixel, and the third sub-pixel.

In some embodiments, as illustrated by FIG. 3, a shortest distance between points on the fifth curved edge 205 and the third curved edge 203 is a first distance, and a shortest distance between points on the sixth curved edge 206 and the fourth curved edge 204 is a second distance, and the first distance and the second distance are equal. With this arrangement, the display substrate can further improve the utilization of the space covered by the light-shielding structure.

In some embodiments, as illustrated by FIG. 3, the second sub-pixel 122 further includes a seventh curved edge 207 and an eighth curved edge 208 disposed opposite each other in a fourth direction D that is perpendicular to the first direction X. At least one of the seventh curved edge 207 and the eighth curved edge 208 is overlapped with an edge of an orthographic projection of the light-shielding structure 150 on the base substrate 110. With this arrangement, the second sub-pixel can also fully utilize the space covered by the light-shielding structure in the fourth direction D, thereby increasing the area of the second sub-pixel.

It is worth noting that, as described above, the display substrate can improve the utilization of the space covered by the light-shielding structure by the above-described setting; at this time, the display substrate can also reduce the orthographic projection area of the light-shielding structure on the base substrate with a certain area of the first sub-pixel, the second sub-pixel, and the third sub-pixel, so as to increase the percentage of the transparent area of the first display area and increase the amount of light intake of the first display area.

In some embodiments, as illustrated by FIG. 3, the display substrate 100 also includes a second pixel group 140; the second pixel group 140 is located in the second display area 114 and includes a fourth sub-pixel 141, a fifth sub-pixel 142, and a sixth sub-pixel 143; in the second pixel group 140, the fourth sub-pixel 141, the fifth sub-pixel 142, and the sixth sub-pixel 143 are sequentially arranged in the third direction Z. For example, the first direction X and the third direction Z are parallel. As a result, in the second display area, the display substrate is not prone to cause a color deviation phenomenon of lines or image edges when displaying lines and image edges extending in different directions. Moreover, when displaying oblique lines, display defects such as a “step” feeling or a “jagged” feeling of the oblique lines can be significantly reduced, thereby improving the display quality of the display substrate.

In some embodiments, as illustrated by FIG. 3, the first sub-pixel 121 and the fourth sub-pixel 141 are configured to emit a first color light, the second sub-pixel 122 and the fifth sub-pixel 142 are configured to emit a second color light, and the third sub-pixel 123 and the sixth sub-pixel 143 are configured to emit a third color light. The area of the first sub-pixel 121 is larger than the area of the fourth sub-pixel 141, and/or, the area of the second sub-pixel 122 is larger than the area of the fifth sub-pixel 142, and/or, the area of the third sub-pixel 123 is larger than the area of the sixth sub-pixel 143; that is, the area of at least one of the first sub-pixel, the second sub-pixel, and the third sub-pixel in the first display area can be larger than the area of the sub-pixel emitting light of a corresponding color in the second display area. Because the brightness of the first pixel group in the first display area is greater than the brightness of the second pixel group in the second display area, the display substrate can have an increased service life by increasing the area of at least one of the first sub-pixel, the second sub-pixel, and the third sub-pixel.

In some embodiments, as illustrated by FIG. 3, the first display area 112 includes a plurality of cell areas 190 that are closely disposed, every N cell area 190 are provided with one first pixel group 120; an orthographic projection of the first pixel group 120 on the base substrate is overlapped with at least one of the cell areas 190, and the value of N is in the range of 3-8. That is, every N cell areas are provided with one first pixel group, and the areas of the N cell areas in which the first pixel group is not arranged can allow light to pass through. As a result, the first display area can realize light-emitting display and allow light to pass through. Moreover, in the case where the value of N is in the range of 3-8, the display quality and the light transmission rate of the first display area are at a good level. It should be noted that, in order to ensure the display quality of the first display area, the brightness of the individual first pixel group is larger than the brightness of the second pixel group.

In some embodiments, as illustrated by FIG. 3, the second display area 114 can also include a plurality of second cell areas 192 that are closely disposed, one second cell area 192 is provided with one second pixel group 140, and the fourth sub-pixel 141, the fifth sub-pixel 142, and the sixth sub-pixel 143 in the second pixel group 140 are all disposed within the corresponding second cell areas 192. The first cell area 190 has the same area as the second cell area 192.

In some embodiments, as illustrated by FIG. 3, every four cell areas 190 are provided with one first pixel group 120. In this case, the display substrate has a better display quality and a better light transmission rate.

In some embodiments, as illustrated by FIG. 3, the fourth sub-pixel 141, the fifth sub-pixel 142, and the sixth sub-pixel 143 are all shaped as rectangles or rounded rectangles. Of course, embodiments of the present disclosure include, but are not limited thereto, the shapes of the fourth sub-pixel, the fifth sub-pixel, and the sixth sub-pixel can also include shapes such as a circle, hexagon, octagon, rhombus, trapezoid, and the like.

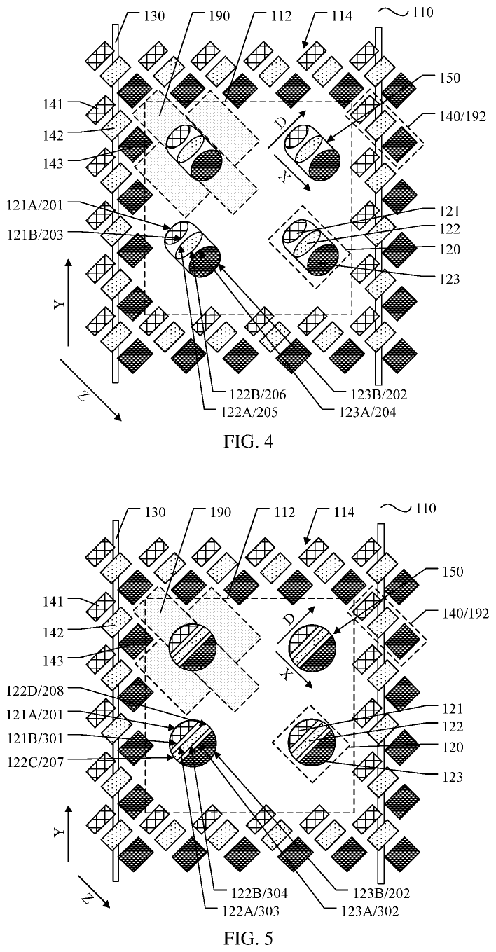

FIG. 4 is a local schematic planar diagram of another display substrate provided by an embodiment of the present disclosure. As illustrated by FIG. 4, the display substrate 100 includes a base substrate 110, a first pixel group 120, and a power line 130. The base substrate 110 includes a first display area 112 and a second display area 114; both the first display area 112 and the second display area 114 are capable of light-emitting display. The first pixel group 120 is located in the first display area 112 and includes a first sub-pixel 121, a second sub-pixel 122, and a third sub-pixel 123; and the power line 130 is located in the second display area 114. The relative positional relationships among the above-described structures can be seen in the relevant description of FIG. 3, and shall not be repeated herein.

As illustrated by FIG. 4, the display substrate 100 further includes a light-shielding structure 150, and an orthographic projection of the light-shielding structure 150 on the base substrate 110 does not include angles; an orthographic projection of the first sub-pixel 121 on the base substrate 110 is located within the orthographic projection of the light-shielding structure 150 on the base substrate 110, and an orthographic projection of the first curved edge 201 of the first sub-pixel 121 on the base substrate 110 is overlapped with an edge of the orthographic projection of the light-shielding structure 150 on the base substrate 110; an orthographic projection of the second sub-pixel 122 on the base substrate 110 is located within the orthographic projection of the light-shielding structure 150 on the base substrate 110; an orthographic projection of the third sub-pixel 123 on the base substrate 110 is located within the orthographic projection of the light-shielding structure 150 on the base substrate 110, and an orthographic projection of the second curved edge 202 of the third sub-pixel 123 on the base substrate 110 is overlapped with an edge of the orthographic projection of the light-shielding structure 150 on the base substrate 110. As a result, by setting the orthographic projection of the light-shielding structure on the base substrate to not include an angle (e.g., a right angle, an obtuse angle, an acute angle, etc.), the display substrate can avoid diffraction phenomenon of external light on the outer edges of the light-shielding structure, and thus can improve the light-sensitive quality of the light-sensitive device provided in the first display area. Moreover, the display substrate can fully utilize the space covered by the light-shielding structure.

In some embodiments, as illustrated by FIG. 4, the second edge 121B of the first sub-pixel 121 is a third curved edge 203, and the third edge 123A of the third sub-pixel 123 is a fourth curved edge 204. The second sub-pixel 122 further includes a fifth curved edge 205 and a sixth curved edge 206 disposed opposite each other in the first direction X. The fifth curved edge 205 is disposed opposite to and spaced apart from the third curved edge 203, and the sixth curved edge 206 is disposed opposite to and spaced apart from the fourth curved edge 204.

In some embodiments, as illustrated by FIG. 4, the first sub-pixel 121, the second sub-pixel 122, and the third sub-pixel 123 are all shaped in ellipses; and intersections of the fifth curved edge 205 and the sixth curved edge 206 are all located at the edges of the orthographic projection of the light-shielding structure 150 on the base substrate 110. As a result, the display substrate can fully utilize the space covered by the light-shielding structure.

In some embodiments, as illustrated by FIG. 4, the shape of the orthographic projection of the light-shielding structure 150 on the base substrate 110 includes a rounded rectangle. In this case, the display substrate better avoid diffraction phenomenon of external light on the outer edges of the light-shielding structure.

FIG. 5 is a local schematic planar diagram of another display substrate provided by an embodiment of the present disclosure. As illustrated by FIG. 5, the display substrate 100 also includes a light-shielding structure 150; the light-shielding structure 150 is located in a first display area 112; the orthographic projections of the first sub-pixel 121, the second sub-pixel 122, and the third sub-pixel 123 of the first pixel group 120 on the base substrate 110 are located within the orthographic projection of the light-shielding structure 150 on the base substrate 110; the shape of the orthographic projection of the light-shielding structure 150 on the base substrate 110 does not include angles.

As illustrated by FIG. 5, because it is no longer the edge of the sub-pixel that affects the light passing through the first display area 112, but the edge of the light shielding structure 150, the second edge 121B of the first sub-pixel 121 can be the first straight edge 301, and the third edge 123A of the third sub-pixel 123 can be the second straight edge 302. The second sub-pixel 122 includes a third straight edge 303 and a fourth straight edge 304 disposed opposite each other in the first direction X. That is, the fifth edge 122A and the sixth edge 122B of the second sub-pixel 122 are both straight edges. The third straight edge 303 is disposed on a side of the fourth straight edge 304 away from the third sub-pixel 123.

In some embodiments, as illustrated by FIG. 5, the first straight edge 301 and the third straight edge 303 are parallel to each other and have a third distance, and the second straight edge 302 and the fourth straight edge 304 are parallel to each other and have a fourth distance. With this arrangement, the spacing between the first straight edge and the third straight edge can be the smallest spacing allowed by the process, and the spacing between the second straight edge and the fourth straight edge can also me the smallest spacing allowed by the process, thereby the display substrate can further increase the utilization of the space covered by the light-shielding structure, and increase the area of the first sub-pixel, the second sub-pixel, and the third sub-pixel.

In some embodiments, as illustrated by FIG. 5, the third distance and the fourth distance are equal. With this arrangement, the display substrate can further improve the utilization of the space covered by the light-shielding structure.

In some examples, as illustrated by FIG. 5, the second sub-pixel 122 further includes a seventh edge 122C and an eighth edge 122D disposed opposite to each other in a fourth direction D perpendicular to the first direction X. At least one of the seventh edge 122C and the eighth edge 122D is overlapped with an edge of an orthographic projection of the light-shielding structure 150 on the base substrate 110. With this arrangement, the second sub-pixel can also fully utilize the space covered by the light-shielding structure in the fourth direction D, thereby increasing the area of the second sub-pixel.

For example, the seventh edge 122C and the eighth edge 122D are both curved edges. Of course, embodiments of the present disclosure include, but are not limited thereto, the seventh edge and the eighth edge can also be straight edges.

In some embodiments, as illustrated by FIG. 5, the shape of an orthographic projection of the light-shielding structure 150 on the base substrate 110 includes a circle. In this case, the display substrate can better avoid diffraction phenomenon of external light on the outer edges of the light-shielding structure.

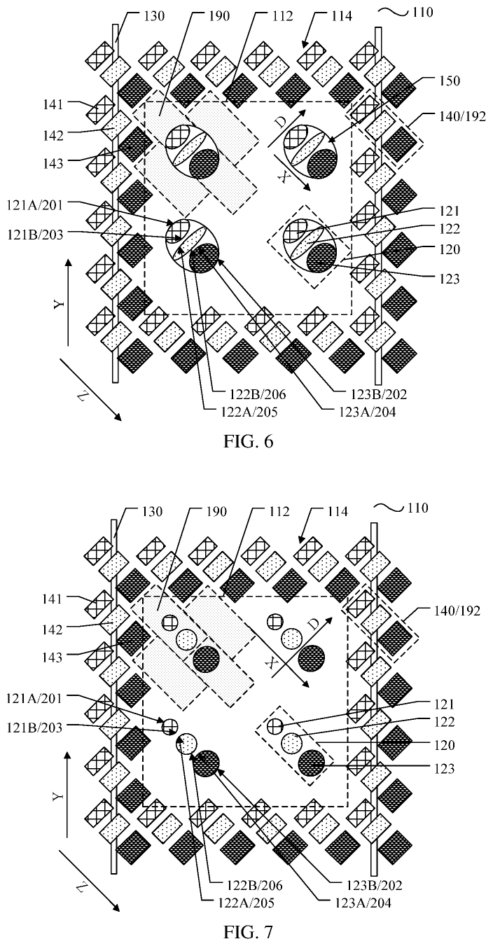

FIG. 6 is a local schematic planar diagram of another display substrate provided by an embodiment of the present disclosure. As illustrated by FIG. 6, the display substrate 100 also includes a light-shielding structure 150; the light-shielding structure 150 is located in a first display area 112; the orthographic projections of the first sub-pixel 121, the second sub-pixel 122, and the third sub-pixel 123 of the first pixel group 120 on the base substrate 110 are located within the orthographic projection of the light-shielding structure 150 on the base substrate 110; the shape of the orthographic projection of the light-shielding structure 150 on the base substrate 110 does not include angles.

As illustrated by FIG. 6, the first sub-pixel 121 includes a first edge 121A and a second edge 121B disposed opposite each other in the first direction X, and the third sub-pixel 123 includes a third edge 123A and a fourth edge 123B disposed opposite each other in the first direction X. The shape of the first sub-pixel 121 includes an ellipse, and two intersections of the first edge 121A and the second edge 121B are disposed on a long axis of the ellipse. The shape of the third sub-pixel 123 includes an ellipse, and two intersections of the third edge 123A and the fourth edge 123B are located on the long axis of the ellipse.

In some embodiments, as illustrated by FIG. 6, the second sub-pixel 122 includes a fifth edge 122A and a sixth edge 122B disposed opposite each other in the first direction X. The fifth edge 122A is disposed on a side of the sixth edge 122B away from the third sub-pixel 123.

In some embodiments, as illustrated by FIG. 6, the shape of the second sub-pixel 122 includes an ellipse, and two intersections of the fifth edge 122A and the sixth edge 122B are disposed on a long axis of the ellipse. And, the two intersections of the fifth edge 122A and the sixth edge 122B are located on the edges of an orthographic projection of the light-shielding structure 150 on the base substrate 110.

In some embodiments, as illustrated by FIG. 6, the shape of the orthographic projection of the light-shielding structure 150 on the base substrate 110 includes an ellipse. In this case, the display substrate can better avoid diffraction phenomenon of external light on the outer edges of the light-shielding structure.

In some embodiments, as illustrated by FIG. 6, the ratio of the long axis to the short axis of the above-described ellipse is in the range of 1-1.3.

FIG. 7 is a local schematic planar diagram of another display substrate provided by an embodiment of the present disclosure. As illustrated by FIG. 7, the display substrate 100 includes a base substrate 110, a first pixel group 120, and a power line 130. The base substrate 110 includes a first display area 112 and a second display area 114; both of the display areas of the display substrate are capable of light-emitting displays, i.e., both the first display area 112 and the second display area 114 are capable of light-emitting displays. The first pixel group 120 is located in the first display area 112 and includes a first sub-pixel 121, a second sub-pixel 122, and a third sub-pixel 123; the power line 130 is located in the second display area 114.

As illustrated by FIG. 7, in the first pixel group 120, the first sub-pixel 121, the second sub-pixel 122, and the third sub-pixel 123 are sequentially arranged along the first direction X; the power line 130 extends along the second direction Y, and the value of the angle between the first direction X and the second direction Y is in the range of 30-60 degrees. The first sub-pixel 121 includes a first edge 121A and a second edge 121B disposed opposite each other in the first direction X, and the third sub-pixel 123 includes a third edge 123A and a fourth edge 123B disposed opposite each other in the first direction X, the first edge 121A is disposed on a side of the second edge 121B away from the second sub-pixel 122, and the fourth edge 123B is disposed on a side of the third edge 123A away from the second sub-pixel 122. The first edge 121A is a first curved edge 201 and the fourth edge 123B is a second curved edge 202.

In the display substrate provided by embodiments of the present disclosure, the angle between the arrangement direction of the first sub-pixel, the second sub-pixel, and the third sub-pixel and the extending direction of the power line is set to 30-60 degrees. As a result, the display substrate is not prone to cause a color deviation phenomenon of lines or image edges when displaying lines and image edges extending in different directions. Moreover, when displaying oblique lines, display defects such as a “step” feeling or a “jagged” feeling of the oblique lines can be significantly reduced, thereby improving the display quality of the display substrate; on the other hand, the display substrate sets at least a part of the first edge of the first sub-pixel and the fourth edge of the third sub-pixel to be curved, which can make the outer edges of the first sub-pixel and the third sub-pixel have no angles and be smoother to avoid the diffraction phenomenon of external light on the outer edges of the first sub-pixel and the third sub-pixel, thereby improving the photosensitive quality of the photosensitive device arranged in the first display area. As a result, the display substrate can simultaneously have higher photosensitive quality and display quality.

In some embodiments, as illustrated by FIG. 7, a maximum distance between the first edge 121A and the second edge 121B is smaller than a maximum distance between the third edge 123A and the fourth edge 123B, and a radius of curvature of the first curved edge 201 is larger than a radius of curvature of the second curved edge 202. As a result, the area of the first sub-pixel is smaller than the area of the third sub-pixel, thereby ensuring that the service life of the first sub-pixel and the third sub-pixel is consistent.

In some embodiments, as illustrated by FIG. 7, the shape of the first sub-pixel 121 includes a first circle, two intersections of the first edge 121A and the second edge 121B are located on a virtual straight line perpendicular to the first direction X and through the center of the first circle.

In some embodiments, as illustrated by FIG. 7, the shape of the third sub-pixel 123 includes a second circle, two intersections of the third edge 123A and the fourth edge 123B are located on a virtual straight line perpendicular to the first direction X and through the center of the second circle.

In some embodiments, as illustrated by FIG. 7, the shape of the second sub-pixel 122 includes a third circle, and the second sub-pixel 122 further includes a fifth edge 122A and a sixth edge 122B disposed opposite each other in the first direction X, the two intersections of the fifth edge 122A and the sixth edge 122B are located on a virtual straight line perpendicular to the first direction X and through the center of the third circle.

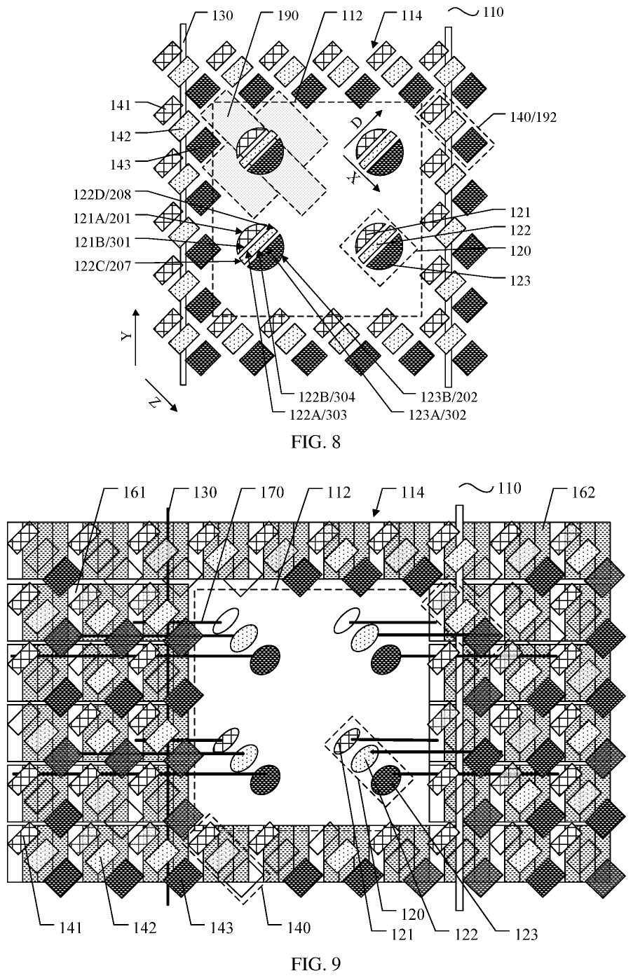

FIG. 8 is a local schematic planar diagram of another display substrate provided by an embodiment of the present disclosure. As illustrated by FIG. 8, the display substrate 100 includes a base substrate 110, a first pixel group 120, and a power line 130. The base substrate 110 includes a first display area 112 and a second display area 114; the first pixel group 120 is located in the first display area 112 and includes a first sub-pixel 121, a second sub-pixel 122, and a third sub-pixel 123; and the power line 130 is located in the second display area 114. In the first pixel group 120, the first sub-pixel 121, the second sub-pixel 122, and the third sub-pixel 123 are sequentially arranged along a first direction X; the power line 130 extends along a second direction Y, and the angle between the first direction X and the second direction Y is in the range of 30-60 degrees.

As illustrated by FIG. 8, the first sub-pixel 121 includes a first edge 121A and a second edge 121B disposed opposite each other in the first direction X, the third sub-pixel 123 includes a third edge 123A and a fourth edge 123B disposed opposite each other in the first direction X, the first edge 121A is disposed on a side of the second edge 121B away from the second sub-pixel 122, and the fourth edge 123B is disposed on a side of the third edge 123A away from the second sub-pixel 122. The first edge 121A of the first sub-pixel 121 is a first curved edge 201 and the second edge 121B of the first sub-pixel 121 is a first straight edge 301; the third edge 123A of the third sub-pixel 123 is a first straight edge 302 and the fourth edge 123B of the third sub-pixel 123 is a second curved edge 202.

In the display substrate, the first edge of the first sub-pixel is a first curved edge and the fourth edge of the third sub-pixel is a second curved edge, which can make the outer edges of the first sub-pixel and the third sub-pixel in the first pixel group have no angles and be smoother to avoid the diffraction phenomenon of external light on the outer edges of the first sub-pixel and the third sub-pixel, thereby improving the photosensitive quality of the photosensitive device arranged in the first display area. As a result, the display substrate can simultaneously have higher photosensitive quality and display quality.

In some embodiments, as illustrated by FIG. 8, the first sub-pixel 121 has a bow-shaped shape, and the third sub-pixel 123 also has a bow-shaped shape.

In some examples, as illustrated by FIG. 8, a length of the second edge 121B of the first sub-pixel 121 is less than a length of the third edge 123A of the third sub-pixel 123.

In some examples, as illustrated by FIG. 8, the second sub-pixel 122 includes a third straight edge 303 and a fourth straight edge 304 disposed opposite each other in the first direction X. The third straight edge 303 is disposed on a side of the fourth straight edge 304 away from the third sub-pixel 123.

FIG. 9 is a connection diagram of a pixel driving circuit of a display substrate provided by an embodiment of the present disclosure. As described in FIG. 9, the display substrate 100 includes a base substrate 110, a first pixel group 120, a power line 130, and a second pixel group 140; The base substrate 110 includes a first display area 112 and a second display area 114; the first pixel group 120 includes a first sub-pixel 121, a second sub-pixel 122 and a third sub-pixel 123; the second pixel group 140 includes a fourth sub-pixel 141, a fifth sub-pixel 142, and a sixth sub-pixel 143. The relative positional relationships of the above-described components can be found in the respective descriptions of the above-described embodiments and will not be repeated herein.

As illustrated by FIG. 9, the display substrate 100 further includes a plurality of first pixel driving circuits 161 and a plurality of second pixel driving circuits 162; each first pixel driving circuit 161 is electrically connected to a first sub-pixel 121, a second sub-pixel 122, or a third sub-pixel 123 in the first pixel group 120, and is configured to drive the corresponding sub-pixel to emit light; each second pixel drive circuit 162 is electrically coupled to a fourth sub-pixel 141, a fifth sub-pixel 142, or a sixth sub-pixel 143 in the second pixel group 140 and is configured to drive the corresponding sub-pixel to emit light.

As illustrated by FIG. 9, the plurality of first pixel driving circuits 161 and the plurality of second pixel driving circuits 162 are located in the second display area 104; the first display area 102 is not provided with pixel driving circuits. In this case, the display substrate further includes a plurality of anode leads 170, the plurality of anode leads 170 being arranged in one-to-one correspondence with the plurality of first pixel driving circuits 161 and electrically connecting the plurality of first pixel driving circuits 161 to the first sub-pixel 121, the second sub-pixel 122, and the third sub-pixel 123 in the first display area 102.

In the display substrate, because the plurality of first pixel driving circuits and the plurality of second pixel driving circuits are all located in the second display area, the pixel driving circuits are not provided in the first display area. As a result, the area occupied by the first pixel group can be reduced in the first display area, and signal lines (e.g., a power line, a data line, a gate line, an initialization signal line, a reset line, and the like) for providing various signals or voltages for the first pixel driving circuits do not have to be provided. Thereby, the percentage of the light-transmitting area in the first display area can be further increased, thereby increasing the light transmission rate of the first display area.

In some embodiments, as described in FIG. 9, the anode lead 170 extends from the second display area 104 to the first display area 102.

In some embodiments, as illustrated by FIG. 9, the second pixel driving circuit 162 can be electrically connected to the corresponding fourth sub-pixel 141, the fifth sub-pixel 142, or the sixth sub-pixel 143 through a via without having to set up an anode lead. Of course, embodiments of the present disclosure include, but are not limited thereto, the second pixel driving circuit and the corresponding sub-pixel can also be staggered and then electrically connected via anode leads.

In some embodiments, as illustrated by FIG. 9, the power line 130 can provide a power supply voltage for the first pixel driving circuit 161 and the second pixel driving circuit 162; the display substrate 100 also includes data lines and gate lines (not shown). The data line can provide a data signal for the first pixel driving circuit 161 and the second pixel driving circuit 162; the gate line can provide a gate signal for the first pixel driving circuit 161 and the second pixel driving circuit 162. It should be noted that for the sake of brevity, FIG. 9 shows only a power line; the setup of the data line and the gate line can be seen in the conventional design.

It is worthy note that the embodiments of the present disclosure are not limited as to the specific structures of the first pixel driving circuit and the second pixel driving circuit. The first pixel driving circuit and the second pixel driving circuit can be structured with a thin film transistor and a storage capacitor or the like, and can for example be formed as a pixel driving circuit structure such as 3T1C, 4T1C, 5T1C, 5T2C, 6T1C, 7T1C, or 8T1C, and the like.

FIG. 10 is a connection diagram of a pixel driving circuit of another display substrate provided by an embodiment of the present disclosure. As described in FIG. 10, the display substrate 100 includes a base substrate 110, a first pixel group 120, a power line 130, a second pixel group 140, and a light-shielding structure 150; the base substrate 110 includes a first display area 112 and a second display area 114; the first pixel group 120 includes a first sub-pixel 121, a second sub-pixel 122, and a third sub-pixel 123; the second pixel group 140 includes a fourth sub-pixel 141, a fifth sub-pixel 142, and a sixth sub-pixel 143; an orthographic projection of the first pixel group 120 on the base substrate 110 falls within an orthographic projection of the light-shielding structure 150 on the base substrate 110. The relative positional relationships of the above-described components can be found in the respective descriptions of the above-described embodiments and will not be repeated herein.

As illustrated by FIG. 10, the display substrate 100 further includes a plurality of first pixel driving circuits 161 and a plurality of second pixel driving circuits 162; each first pixel driving circuit 161 is electrically connected to a first sub-pixel 121, a second sub-pixel 122, or a third sub-pixel 123 in the first pixel group 120, and is configured to drive the corresponding sub-pixel to emit light; each second pixel drive circuit 162 is electrically coupled to a fourth sub-pixel 141, a fifth sub-pixel 142, or a sixth sub-pixel 143 in the second pixel group 140 and is configured to drive the corresponding sub-pixel to emit light.

As illustrated by FIG. 10, the first pixel driving circuit 161 is located in the first display area 102; the second pixel driving circuit 162 is located in the second display area 104. In this case, the orthographic projection of the first pixel driving circuit 161 on the base substrate 110 is also located within the orthographic projection of the light-shielding structure 150 on the base substrate 110.

In this display substrate, because a light-shielding structure has been provided, the first pixel driving circuit can be provided within the range covered by the light-shielding structure, and thus the structure can be simplified.

In some embodiments, as illustrated by FIG. 10, in order to provide a power supply voltage to the first pixel driving circuit 161, the power line 130 corresponding to the second pixel driving circuit 162 located in the same column as the first pixel driving circuit 161 can pass through the first display area 102.

In some embodiments, as illustrated by FIG. 10, the display substrate 100 further includes a data line 181 and a gate line 182. The data line 181 can provide data signals for the first pixel driver circuit 161 and the second pixel driver circuit 162; the gate line 182 can provide a gate signal for the first pixel driving circuit 161 and the second pixel driving circuit 162. Similar to the power line 130, the data line 181 corresponding to the second pixel driver circuit 162 located in the same column as the first pixel driver circuit 161 can pass through the first display area 102, and the gate line 192 corresponding to the second pixel driver circuit 162 located in the same row as the first pixel driver circuit 161 can pass through the first display area 102. It should be noted that for the sake of brevity, FIG. 10 shows only three sets of power lines and data lines and two gate lines.

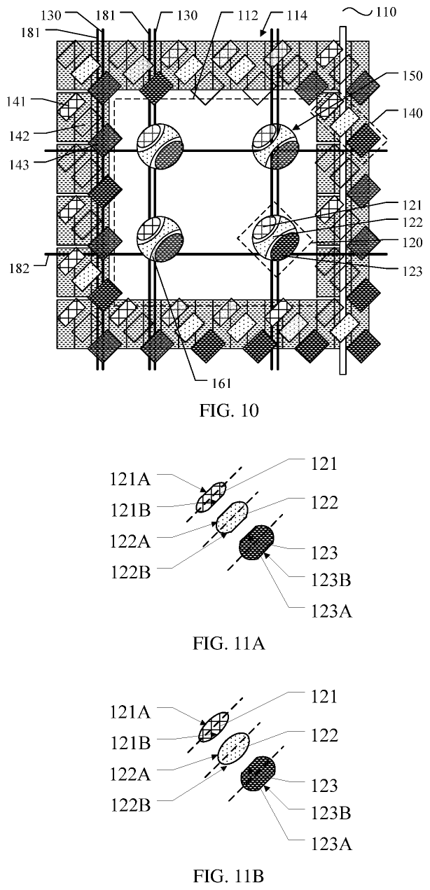

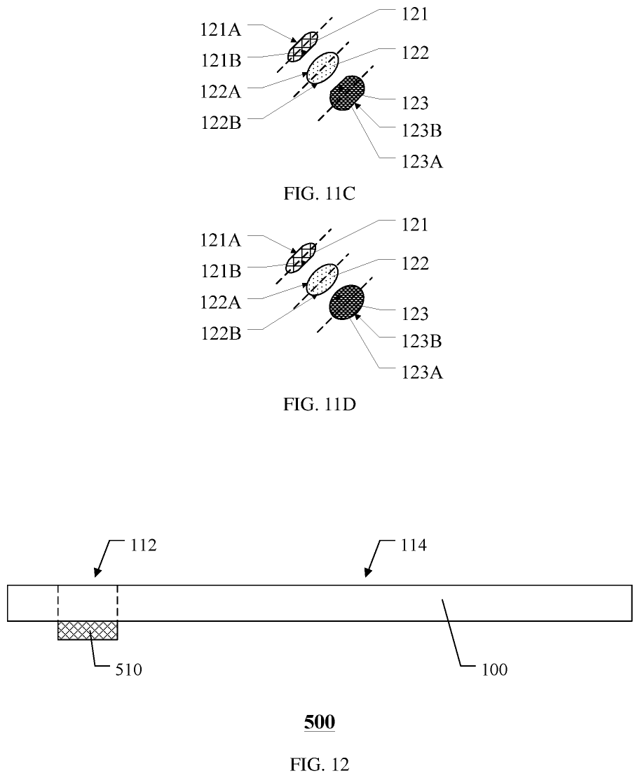

FIGS. 11A-11D are schematic planar diagrams of a first pixel group of a display substrate provided by an embodiment of the present disclosure. The first pixel groups shown in FIGS. 11A-11D can all be applied in the display substrate shown in FIG. 2. That is, the first pixel group 120 shown in FIGS. 11A-11D can be located in a first display area 112; the first sub-pixel 121, the second sub-pixel 122, and the third sub-pixel 123 in the first sub-pixel group 120 are sequentially arranged along a first direction X; the power line 130 extends along a second direction Y, and the value of the angle between the first direction X and the second direction Y is in the range of 30-60 degrees.

As illustrated by FIG. 11A, the first sub-pixel 121 includes a first edge 121A and a second edge 121B disposed opposite each other in the first direction X, and the third sub-pixel 123 includes a third edge 123A and a fourth edge 123B disposed opposite each other in the first direction X, the first edge 121A is disposed on a side of the second edge 121B away from the second sub-pixel 122, and the fourth edge 123B is disposed on a side of the third edge 123A away from the second sub-pixel 122. At least a part of the first edge 121A is curved, but the first edge 121A can also include a straight portion; for example, the first edge 121A can be a combination of a straight portion and two curved portions, the two curved portions being connected to two ends of the straight portion. Similarly, at least a part of the fourth edge 123B is curved, but the fourth edge 123B can also include a straight portion; for example, the fourth edge 123B can also be a combination of a straight portion and two curved portions. In this case, although the first edge and the fourth edge both include straight portions, the straight portions of the first edge and the fourth edge are provided with curved portions at both ends and no angles are formed. As a result, the outer edges of the first sub-pixel and the third sub-pixel do not have angles and are smoother, so that diffraction phenomenon of external light on the outer edges of the first sub-pixel and the third sub-pixel can be avoided, and the light-sensitive quality of the light-sensitive device provided in the first display area can thus be improved. For example, in the case where the light-sensitive device is a camera, the above-described light-sensitive quality is an imaging quality. It should be noted that the above-described first edge and the second edge can be two continuous edges separated by a straight line perpendicular to the first direction. Of course, embodiments of the present disclosure include, but are not limited thereto, that the above-described first edge and second edge can also be two edges that are not connected.

On the other hand, because the first pixel group shown in FIG. 11A can be applied in the display substrate shown in FIG. 2, the angle between the arrangement direction of the first sub-pixel, the second sub-pixel, and the third sub-pixel and the extending direction of the power line is set to 30-60 degrees. As a result, the display substrate is not prone to cause a color deviation phenomenon of lines or image edges when displaying lines and image edges extending in different directions. Moreover, when displaying oblique lines, display defects such as a “step” feeling or a “jagged” feeling of the oblique lines can be significantly reduced, thereby improving the display quality of the display substrate. As a result, the display substrate can simultaneously have higher photosensitive quality and display quality.

In some embodiments, as illustrated by FIG. 11A, the second edge 121B can be a combination of a straight portion and two curved portions, the two curved portions being connected to two ends of the straight portion. Similarly, the third edge 123A can be a combination of a straight portion and two curved portions. Of course, embodiments of the present disclosure include, but are not limited thereto, the second edge and third edge can both be continuous curved sides.

In some embodiments, as illustrated by FIG. 11A, the second sub-pixel 122 further includes a fifth edge 122A and a sixth edge 122B disposed opposite each other in the first direction X; the fifth edge 122A can be a combination of a straight portion and two curved portions, the two curved portions are connected to the two ends of the straight portion, respectively. Similarly, the sixth edge 122B can be a combination of a straight portion and two curved portions.

In some embodiments, the above-described first direction can be an extending direction of a line connecting the centers of the first sub-pixel, the second sub-pixel, and the third sub-pixel; alternatively, a straight line extending along the first direction can divide the first sub-pixel, the second sub-pixel, and the third sub-pixel into two parts, respectively, with a ratio of the areas of the two parts being between 0.5 and 2.

As illustrated by FIG. 11B, the first sub-pixel 121 includes a first edge 121A and a second edge 121B disposed opposite each other in the first direction X, and the third sub-pixel 123 includes a third edge 123A and a fourth edge 123B disposed opposite each other in the first direction X, the first edge 121A is disposed on a side of the second edge 121B away from the second sub-pixel 122, and the fourth edge 123B is disposed on a side of the third edge 123A away from the second sub-pixel 122. The first edge 121A is a continuous curved side and does not include the above-described straight portion; the fourth edge 123B is at least partially curved but the fourth edge 123B can also include a straight portion; for example, the fourth edge 123B can also be a combination of one straight portion and two curved portions. In this case, the outer edges of the first sub-pixel and the third sub-pixel do not have angles and are smoother, so that diffraction phenomenon of external light on the outer edges of the first sub-pixel and the third sub-pixel can be avoided, and the light-sensitive quality of the light-sensitive device provided in the first display area can thus be improved; for example, in the case where the light-sensitive device is a camera, the above-described light-sensitive quality is an imaging quality.

On the other hand, because the first pixel group shown in FIG. 11B can be applied in the display substrate shown in FIG. 2, the angle between the arrangement direction of the first sub-pixel, the second sub-pixel, and the third sub-pixel and the extending direction of the power line is set to 30-60 degrees. As a result, the display substrate is not prone to cause a color deviation phenomenon of lines or image edges when displaying lines and image edges extending in different directions. Moreover, when displaying oblique lines, display defects such as a “step” feeling or a “jagged” feeling of the oblique lines can be significantly reduced, thereby improving the display quality of the display substrate. As a result, the display substrate can simultaneously have higher photosensitive quality and display quality.

In some embodiments, as illustrated by FIG. 11B, the second edge 121B can be a continuous curved edge. The third edge 123A can also be a combination of one straight portion and two curved portions. Of course, embodiments of the present disclosure include, but are not limited thereto, the second edge can be a combination of one straight portion and two curved portions, and the third edge can also be a continuous curved edge.

In some embodiments, as illustrated by FIG. 11B, the second sub-pixel 122 further includes a fifth edge 122A and a sixth edge 122B disposed opposite each other in the first direction X; the fifth edge 122A can be a continuous curved edge. Similarly, the sixth edge 122B can be a continuous curved edge.

As illustrated by FIG. 11C, the first sub-pixel 121 includes a first edge 121A and a second edge 121B disposed opposite each other in the first direction X, and the third sub-pixel 123 includes a third edge 123A and a fourth edge 123B disposed opposite each other in the first direction X, the first edge 121A is disposed on a side of the second edge 121B away from the second sub-pixel 122, and the fourth edge 123B is disposed on a side of the third edge 123A away from the second sub-pixel 122. The first edge 121A can be a combination of a straight portion and two curved portions; the fourth edge 123B is at least partially curved but can also include a straight portion; for example, the fourth edge 123B can also be a combination of a straight portion and two curved portions. In this case, the outer edges of the first sub-pixel and the third sub-pixel do not have angles and are smoother, so that diffraction phenomenon of external light on the outer edges of the first sub-pixel and the third sub-pixel can be avoided, and the light-sensitive quality of the light-sensitive device provided in the first display area can thus be improved; For example, in the case where the light-sensitive device is a camera, the above-described light-sensitive quality is an imaging quality.

On the other hand, because the first pixel group shown in FIG. 11C can be applied in the display substrate shown in FIG. 2, the angle between the arrangement direction of the first sub-pixel, the second sub-pixel, and the third sub-pixel and the extending direction of the power line is set to 30-60 degrees. As a result, the display substrate is not prone to cause a color deviation phenomenon of lines or image edges when displaying lines and image edges extending in different directions. Moreover, when displaying oblique lines, display defects such as a “step” feeling or a “jagged” feeling of the oblique lines can be significantly reduced, thereby improving the display quality of the display substrate; As a result, the display substrate can simultaneously have higher photosensitive quality and display quality.

In some embodiments, as illustrated by FIG. 11C, the second edge 121B can be a combination of a straight portion and two curved portions, the two curved portions being coupled to each end of the straight portion. Similarly, the third edge 123A can be a combination of a straight portion and two curved portions. Of course, embodiments of the present disclosure include, but are not limited thereto, the second and third edges can both be continuous curved sides.

In some embodiments, as illustrated by FIG. 11C, the second sub-pixel 122 further includes a fifth edge 122A and a sixth edge 122B disposed opposite each other in the first direction X; the fifth edge 122A can be a continuous curved edge. Similarly, the sixth edge 122B can be a continuous curved edge.

As illustrated by FIG. 11D, the first sub-pixel 121 includes a first edge 121A and a second edge 121B disposed opposite each other in the first direction X, and the third sub-pixel 123 includes a third edge 123A and a fourth edge 123B disposed opposite each other in the first direction X, the first edge 121A is disposed on a side of the second edge 121B away from the second sub-pixel 122, and the fourth edge 123B is disposed on a side of the third edge 123A away from the second sub-pixel 122. The first edge 121A can be a combination of a straight portion and two curved portions; the fourth edge 123B is a continuous curved side. In this case, the outer edges of the first sub-pixel and the third sub-pixel do not have angles and are smoother, so that diffraction phenomenon of external light on the outer edges of the first sub-pixel and the third sub-pixel can be avoided, and the light-sensitive quality of the light-sensitive device provided in the first display area can thus be improved. For example, in the case where the light-sensitive device is a camera, the above-described light-sensitive quality is an imaging quality.

On the other hand, because the first pixel group shown in FIG. 11D can be applied in the display substrate shown in FIG. 2, the angle between the arrangement direction of the first sub-pixel, the second sub-pixel, and the third sub-pixel and the extending direction of the power line is set to 30-60 degrees. As a result, the display substrate is not prone to cause a color deviation phenomenon of lines or image edges when displaying lines and image edges extending in different directions. Moreover, when displaying oblique lines, display defects such as a “step” feeling or a “jagged” feeling of the oblique lines can be significantly reduced, thereby improving the display quality of the display substrate. As a result, the display substrate can simultaneously have higher photosensitive quality and display quality.

In some embodiments, as illustrated by FIG. 11D, the second edge 121B can be a combination of a straight portion and two curved portions, the two curved portions being connected to the ends of the straight portion. Similarly, the third edge 123A can be a continuous curved edge.

In some embodiments, as illustrated by FIG. 11D, the second sub-pixel 122 further includes a fifth edge 122A and a sixth edge 122B disposed opposite each other in the first direction X; the fifth edge 122A can be a continuous curved edge. Similarly, the sixth edge 122B can be a continuous curved edge.

An embodiment of the present disclosure also provides a display device. FIG. 12 is a diagram of a display device provided by an embodiment of the present disclosure. An embodiment of the present disclosure also provides a display device. FIG. 12 shows a schematic diagram of a display device provided by an embodiment of the present disclosure. As illustrated by FIG. 12, the display device 500 includes the above-described display substrate 100. As a result, the display device has a beneficial effect corresponding to the beneficial effect of the above-described display substrate, such as the display device having a higher display quality while having a better light-sensitive quality in the first display area.

In some embodiments, as illustrated by FIG. 12, the display device 500 further includes a light-sensitive device 510; an orthographic projection of the light-sensitive device 510 on the base substrate 110 is located in the first display area 102. thereby, the light-sensitive device can receive light transmitted through the first display area of the display substrate, thereby realizing various functions, such as taking a picture, facial recognition, fingerprint recognition, and the like. In addition, the display device can realize a large screen-to-body ratio with an integration of the photoreceptor.

In some embodiments, the above-described light-sensitive device 510 can include at least one of a camera, an optical fingerprint recognition sensor, a facial recognition sensor, an infrared sensor, and a distance sensor.

In some embodiments, the above-described display device 500 can be an electronic product with a display function such as a smartphone, a tablet computer, a navigator, a monitor, a television, and the like.

The following points need to be explained:
(1) In the drawings of the embodiment of the present disclosure, only the structure related to the embodiment of the present disclosure is involved, and other structures can refer to the general design.
(2) Features in the same embodiment and different embodiments of the present disclosure can be combined with each other without conflict.

The above is only the specific embodiment of this disclosure, but the protection scope of this disclosure is not limited to this. Any person familiar with the technical field can easily think of changes or substitutions within the technical scope disclosed in this disclosure, and they should be included in the protection scope of this disclosure. Therefore, the scope of protection of this disclosure should be based on the scope of protection of the claims.

1. A display substrate, comprising:
a base substrate, comprising a first display area and a second display area;
a first pixel group, located in the first display area and comprising a first sub-pixel, a second sub-pixel, and a third sub-pixel; and
a power line, located in the second display area,
wherein, in the first pixel group, the first sub-pixel, the second sub-pixel, and the third sub-pixel are arranged in sequence in a first direction; the power line extends in a second direction, and a value of an angle between the first direction and the second direction ranges from 30 to 60 degrees;
the first sub-pixel includes a first edge and a second edge disposed opposite each other in the first direction, and the third sub-pixel includes a third edge and a fourth edge disposed opposite each other in the first direction, the first edge is disposed on a side of the second edge away from the second sub-pixel, the fourth edge is disposed on a side of the third edge away from the second sub-pixel, at least a part of the first edge is curved, and at least a part of the fourth edge is curved.

2. The display substrate according to claim 1, wherein the first edge is a first curved edge and the fourth edge is a second curved edge.

3. The display substrate according to claim 1, wherein a pixel density of the first display area is less than a pixel density of the second display area, and an included angle between the first direction and the second direction ranges from 40 to 50 degrees.

4. The display substrate according to claim 1, further comprising:
a second pixel group, located in the second display area and includes a fourth sub-pixel, a fifth sub-pixel, and a sixth sub-pixel;
wherein, in the second pixel group, the fourth sub-pixel, the fifth sub-pixel, and the sixth sub-pixel are arranged in sequence along a third direction;
the first sub-pixel and the fourth sub-pixel are configured to emit light of a first color, the second sub-pixel and the fifth sub-pixel are configured to emit light of a second color, and the third sub-pixel and the sixth sub-pixel are configured to emit light of a third color;
an area of the first sub-pixel is larger than an area of the fourth sub-pixel, and/or, an area of the second sub-pixel is larger than an area of the fifth sub-pixel, and/or, an area of the third sub-pixel is larger than an area of the sixth sub-pixel.

5. The display substrate according to claim 4, wherein an extending direction of the first sub-pixel and an extending direction of the fourth sub-pixel are the same or parallel.

6. (canceled)

7. The display substrate according to claim 4, wherein an angle between the first direction and the third direction is in a range of 0-10 degrees.

8. (canceled)

9. The display substrate according to claim 1, further comprising:
a light-shielding structure, located in the first display area;
wherein an orthographic projection of the first edge of the first sub-pixel on the base substrate is overlapped with an orthographic projection of the light-shielding structure on the base substrate; an orthographic projection of the fourth edge of the third sub-pixel on the base substrate is overlapped with the orthographic projection of the light-shielding structure on the base substrate,
an outline of the light-shielding structure is a shape surrounded by arcs; alternatively, an outline of the light-shielding structure is a shape surrounded by arcs and a straight line segment, and both ends of the straight line segments are connected to the arcs.

10. The display substrate according to claim 9, wherein a shape of the orthographic projection of the light-shielding structure on the base substrate does not include an angle, the angle being formed by an intersection of two straight line segments.

11. The display substrate according to claim 9, wherein at least a part of the outline of the light-shielding structure is overlapped with a part of an edge of at least one sub-pixel of the first sub-pixel, the second sub-pixel, and the third sub-pixel.

12. The display substrate according to claim 11, wherein at least a part of the outline of the light-shielding structure has intersections with an edge of the first sub-pixel, an edge of the second sub-pixel, and an edge of the third sub-pixel.

13-14. (canceled)

15. The display substrate according to claim 9, wherein at least a part of at least one of the first edge and the fourth edge is overlapped with an edge of the orthographic projection of the light-shielding structure on the base substrate.

16. (canceled)

17. The display substrate according to claim 9, wherein the second edge is a third curved edge and the third edge is a fourth curved edge.

18. The display substrate according to claim 17, wherein the second sub-pixel further comprises a fifth curved edge and a sixth curved edge disposed opposite to each other in the first direction, the fifth curved edge is disposed opposite to and spaced apart from the third curved edge, and the sixth curved edge is disposed opposite to and spaced apart from the fourth curved edge,
points on the fifth curved edge have substantially equal shortest distances from the third curved edge, and points on the sixth curved edge have substantially equal shortest distances from the fourth curved edge.

19. (canceled)

20. The display substrate according to claim 17, wherein the second sub-pixel further comprises a seventh curved edge and an eighth curved edge disposed opposite each other in a fourth direction that is perpendicular to the first direction, at least one of the seventh curved edge and the eighth curved edge is overlapped with an edge of an orthographic projection of the light-shielding structure on the base substrate.

21. The display substrate according to claim 9, wherein the second edge of the first sub-pixel is a first straight edge, and the third edge of the third sub-pixel is a second straight edge, the second sub-pixel comprises a third straight edge and a fourth straight edge disposed opposite each other in the first direction, the third straight edge is disposed on a side of the fourth straight edge away from the third sub-pixel.

22-23. (canceled)

24. The display substrate according to claim 9, wherein a geometric center of an orthographic projection of the light-shielding structure on the base substrate is located between the first sub-pixel and the third sub-pixel.

25. The display substrate according to claim 1, wherein a maximum distance between the first edge and the second edge is smaller than a maximum distance between the third edge and the fourth edge.

26. The display substrate according to claim 1, wherein a shape of the first sub-pixel comprises a first ellipse, two intersections of the first edge and the second edge are located on a long axis of the first ellipse.

27-28. (canceled)

29. The display substrate according to claim 1, wherein a shape of the first sub-pixel comprises a first circle, two intersections of the first edge and the second edge are located on a virtual straight line perpendicular to the first direction and through a center of the first circle.

30-34. (canceled)

35. A display device, comprising:
the display substrate according to claim 1; and
a light-sensitive device,
wherein an orthographic projection of the light-sensitive device on the base substrate is located in the first display area.

36. (canceled)
